(19) United States
(12) Patent Application Publication
(10) Pub. No.: US 2025/0144816 A1
(43) Pub. Date: May 8, 2025

(54) METHOD OF TRANSFERRING AN OBJECT USING A STAMP WITH SHAPE MEMORY POLYMER NANOTIPS

(71) Applicant: POSTECH RESEARCH AND BUSINESS DEVELOPMENT FOUNDATION, Pohang-si (KR)

(72) Inventors: Seok KIM, Pohang-si (KR); Jun Hyung KIM, Pohang-si (KR)

(21) Appl. No.: 18/908,921

(22) Filed: Oct. 8, 2024

(30) Foreign Application Priority Data
Nov. 7, 2023 (KR) 10-2023-0152422

(51) Int. Cl. B25J 15/00; F03G 7/06; G03F 7/00

(52) U.S. Cl. CPC B25J 15/008; F03G 7/0612; G03F 7/0002

(57) ABSTRACT

Disclosed is a transfer technology, in which a shape memory polymer surface with dense nanotips is designed to apply a micro-sized object such as a micro-LED to a mass transfer technology. According to the disclosure, the nanotip shape memory polymer surface is in contact with objects in a heated state, and the nanotip shape memory polymer surface in the heated state is excellent in surface adaptability, thereby attaching/embedding and transferring micro-sized objects.

### CROSS REFERENCE TO RELATED APPLICATION

This application claims the benefit of priority to Korean patent application number 10-2023-0152422 filed on Nov. 7, 2023, the entire disclosure of which is incorporated herein by reference in its entirety.

### BACKGROUND OF THE INVENTION

### Field of the Invention

The disclosure relates to a method of transferring object using shape memory polymer nanotips by controlling adhesion according to the characteristics of a shape memory polymer.

### Description of the Related Art

As one of major modern technologies, a micro light emitting diode (LED) refers to a display type that uses a very small LED as a pixel. Compared to an organic light emitting diode (OLED), i.e., one of display technologies that are currently attracting a lot of attention, the micro-LED has several advantages such as higher brightness, better pixels, higher energy efficiency, improved durability, and longer lifespan. Due to these advantages, display industry and academia are very interest in research on the micro-LED.

However, it is complicated to fabricate the micro-LED. A process of precisely arranging and connecting millions of micro-LEDs requires a high level of technical skills, thereby taking a long time to fabricate and increasing costs. Further, a process of repairing the micro-LED is not completely established yet, and it is thus difficult to individually replace or repair a defective pixel. To solve these problems, active researches have been in progress, and, in particular, researches on technology for transferring a small-sized LED pixel at a high yield are emerging as major interest. In addition, to efficiently commercialize the micro-LED, it is necessary to develop technology for quickly and effectively repairing the defective pixel.

The micro-LED is attracting attention as a major technology in the upcoming display era. The process of effectively transferring such small LED pixels plays a decisive role in the commercialization of this technology, and thus various transfer methods have been studied so far. Among the transfer methods being studied, the elastomer stamp-based transfer method and a fluidic self-assembly method are representative.

The transfer using the elastomer stamp is based on controlling the adhesion of the stamp in the process of transferring the micro-LED. This method employs a commonly used elastomer called polydimethylsiloxane (PDMS), and is carried out by a transfer speed control method, a laser utilization method, etc. However, it is difficult to secure a high yield due to a limited range of controlling the adhesion of the PDMS stamp. Further, the PDMS stamp has a problem of being difficult to use in the repairing process because its adhesion is relatively weaker than that of an adhesive layer of a micro-LED receiving substrate.

On the other hand, the fluidic self-assembly method has a great advantage in arranging the micro-LED pixels at a high yield. However, this technology has limitations in that deterministic assembly is not ensured, in particular, the deterministic assembly is not performed in terms of the micro-LED technology that requires accurate arrangement of three colors R, G and B. Further, inability to remove the defective pixel after the assembly is considered the major weakness of the fluidic self-assembly method.

### DOCUMENTS OF RELATED ART

Patent Document U.S. Pat. No. 11,302,561

### SUMMARY OF THE INVENTION

An aspect of the disclosure is to provide a method of transferring an object using a stamp with shape memory polymer nanotips, which can selectively pick up and release a conventional micro scale object.

According to the disclosure, there is provided a method of transferring at least one object using a stamp with shape memory polymer tips includes: a heating step in which a plurality of nanotips protruding from an attachment surface is heated to a critical temperature or higher; a contacting step in which an outer surface of at least one nanotips comes into contact with the object; a pressing step in which the attachment surface is at least partially decreased in roughness to attach the object thereto; a cooling step in which the nanotips in a pressed state are cooled below the critical temperature; an aligning step in which the attached object is arranged on a receiving substrate; and a transferring step in which the nanotips arranged on the receiving substrate are heated to the critical temperature or higher to transfer a transfer object to the receiving substrate.

Meanwhile, in the pressing step, the stamp may be decreased in surface roughness by the object.

Meanwhile, the stamp may include the shape memory polymer tips regularly or randomly arranged on the attachment surface.

Further, the nanotip may be smaller than the object.

Meanwhile, the nanotip may be at least partially shaped to have a smaller cross-sectional area toward an end portion thereof.

Meanwhile, in the contacting step, an end portion of at least one first nanotip may come into contact with the object, and an inclined surface of at least one second nanotip may come into contact with the object.

Meanwhile, in the pressing step, a contact surface may be formed as the first nanotips is pressed against the object.

Further, in the pressing step, the edge of the object may be at least partially embedded in the second nanotips.

In addition, in the pressing step, a plurality of edges of the objects are simultaneously embedded in the plurality of second nanotips.

Meanwhile, in the pressing step, the opposite edges of the object are simultaneously embedded in the second tips.

Further, in the pressing step, the formation of the contact surface in the first nanotips and the embedment in the second nanotips may be performed simultaneously.

Meanwhile, in the transferring step, the contact surface may disappear as the first nanotips are restored to their original shapes.

Meanwhile, the embedment in the second nanotips may be released as the second nanotips are restored to their original shapes.

In addition, the heating step may be performed by heating the nanotips to the glass transition temperature or higher.

Meanwhile, the heating step may be performed by at least one of laser assisted heating, resistive heating, conduction heating, and convection heating.

Meanwhile, the nanotips may be provided on a support layer, and the support layer may be made of a material that is less thermally deformed than the nanotips.

Meanwhile, the cooling step is performed by cooling the nanotips below the glass transition temperature.

In addition, the cooling step may be performed by at least one of conduction cooling, convection cooling, and radiational cooling.

Further, the heating step, the cooling step, and the transferring step may be performed for a portion of the stamp.

In addition, at least some among a plurality of objects arranged on an area of the stamp may be selectively transferred.

Meanwhile, the plurality of nanotips may be regularly arranged on the attachment surface.

### BRIEF DESCRIPTION OF THE DRAWINGS

FIG. 1 is a flowchart of method of transferring an object using a stamp with shape memory polymer nanotips according to the disclosure.

FIG. 2 is a conceptual diagram showing the characteristics of a stamp based on shape memory polymer nanotips according to the disclosure, which is varied depending on temperature.

FIG. 3 is a graph showing the characteristics of a stamp based on shape memory polymer nanotips according to the disclosure, which is varied depending on temperature.

FIG. 4 shows surface images of a stamp based on shape memory polymer nanotips when turned on/off, along with conceptual diagrams of the nanotips.

FIGS. 5A and 5B are graphs showing relationships between the roughness and adhesion on an attachment surface of a stamp according to the disclosure.

FIGS. 6A and 6B are images showing that an object is picked up by a stamp based on shape memory polymer nanotips according to the disclosure.

FIGS. 7A and 7B are conceptual diagrams showing another example that the object is picked up by a stamp based on shape memory polymer nanotips according to the disclosure.

FIG. 8 shows images of the object picked up by a stamp based on shape memory polymer nanotips according to the disclosure.

FIG. 9 is a conceptual diagram showing a process of picking up a stamp based on shape memory polymer nanotips according to the disclosure.

FIG. 10 is a conceptual diagram showing a process of releasing a stamp based on shape memory polymer nanotips according to the disclosure.

FIG. 11 is a conceptual diagram showing a mass-transfer process using a stamp based on shape memory polymer nanotips according to the disclosure.

FIG. 12 shows result images of the object mass-transferred using a stamp based on shape memory polymer nanotips according to the disclosure.

FIG. 13 is a conceptual diagram showing that a micro-LED is replaced using a stamp based on shape memory polymer nanotips according to the disclosure.

FIG. 14 shows a result image of the object selectively transferred using a stamp based on shape memory polymer nanotips according to the disclosure.

FIG. 15 is a conceptual diagram showing a method of fabricating a stamp based on shape memory polymer nanotips according to the disclosure.

### DETAILED DESCRIPTION OF THE INVENTION

Below, a method of transferring an object using a stamp with shape memory polymer nanotips according to an embodiment of the disclosure will be described in detail with reference to the accompanying drawings. In the following description, the names of components used may be referred to as other names in this art. However, these components may be considered as equivalent components in alternative embodiments if they are functionally similar or identical to each other. Further, the reference numerals of the components are merely given for the convenience of description. However, the components indicated by the reference numerals in the accompanying drawings are not limited by those shown therein. Likewise, if components are functionally similar or identical to each other even though they are partially modified in the drawings according to alternative embodiments, the components may be considered as the equivalent components. Further, when components are recognized as components that should be included at the level of those skilled in the art, they are not described. In addition, if it is obvious to those skilled in the art that a component should be included, descriptions thereof will be omitted.

Hereafter, the term ‘object’ refers to the ink that is transferred during manufacturing process, repairing process, etc., that is, the ink that can be picked up and placed. Furthermore, the object can be micro-sized, such as a micro material piece, micro semiconductor, Micro LED, or Micro Device. Additionally, the object may be an element, material, or device with an area larger than the attachment surface of the stamp.

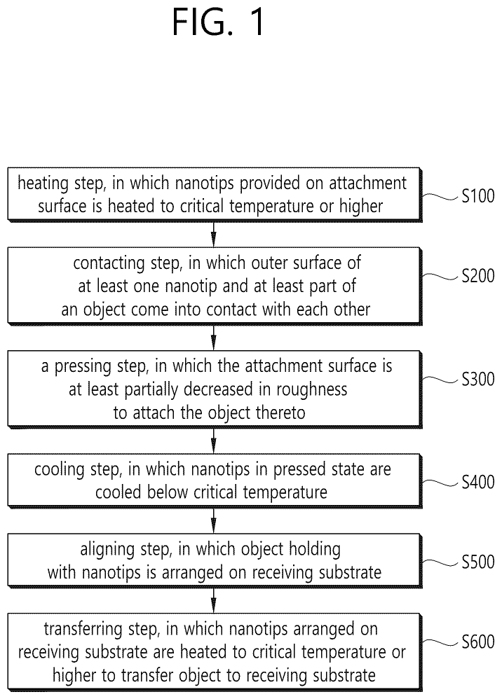

FIG. 1 is a flowchart of a method of transferring an object using a stamp with shape memory polymer nanotips according to the disclosure.

Referring to FIG. 1, a method of transferring an object using a stamp with shape memory polymer nanotips according to the disclosure may include a heating step S100 in which a plurality of nanotips protruding from an attachment surface is heated to a critical temperature or higher, a contacting step S200 in which the object comes into contact with an outer surface of at least one nanotip, a pressing step S300 in which the attachment surface is at least partially decreased in roughness to attach the object thereto, a cooling step S400 in which the pressed nanotips are cooled below the critical temperature, an aligning step S500 in which the object holding with the nanotips is arranged on a receiving substrate, and a transferring step S600 in which the nanotips arranged on the receiving substrate are heated to the critical temperature or higher to transfer a transfer object to the receiving substrate.

The heating step S100, in which the plurality of nanotips protruding from the attachment surface is heated to the critical temperature or higher, refers to a step of heating a shape memory polymer to a glass transition temperature or higher so as to become a soft rubbery state. In this step, a stamp formed with the plurality of nanotips on one surface of a support layer may be employed. The plurality of nanotips refers to nano-sized protrusions, which may be arranged regularly or randomly on the attachment surface. This step of heating the nanotips may include heating all the nanotips to the glass transition temperature or higher. Meanwhile, in this step, only a partial area of the stamp may be heated. Such partial heating may be performed to selectively transfer the object.

Meanwhile, the heating in this step S100 may be achieved by at least one of laser assisted heating, resistive heating, conduction heating, and convection heating.

The contacting step S200, in which the object comes into contact with the outer surface of at least one nanotip, refers to a step of moving the stamp closer to the object in a state that the stamp is aligned with the object. Each nanotip may be shaped to have a smaller cross-sectional area toward the end thereof, i.e., as it gets closer to the object in the state that the stamp faces the object. In other words, the nanotip may be structured to have a sharp end portion. For example, the nanotip may have a pyramid structure, a hemisphere structure, an elliptical hemisphere structure, etc. In this case, the nanotips may be formed on the attachment surface of the stamp regularly or randomly in a horizontal direction, and may have heights regularly or randomly within a predetermined range.

Therefore, in this step, the ends of the plurality of nanotips may come into contact with the object. Further, lateral sides of other nanotips may come into contact with an edge of the object.

The pressing step S300, in which the attachment surface is at least partially decreased in roughness to attach the object thereto, refers to a step of pressing the stamp according to the disclosure toward the object (or pressing the object toward the stamp) by an external actuator. In this step, the plurality of nanotips provided in the stamp are in the soft rubbery state. Therefore, when the stamp is pressed toward the object, a contact surface of the stamp may be varied in shape depending on the shape of the object. The deformation of the stamp may be varied depending on how pressed it is. When the stamp is fully pressed, all the nanotips may be deformed on the attachment surface facing the object. In this case, the nanotips deformed as pressed by the object cause the contact surface of the stamp to be changed in roughness. As the roughness of the contact surface decreases, the adhesion may increase.

Meanwhile, the object may have a contact area with the stamp, which is smaller than an attachment portion of the stamp. In this case, at least one of the nanotips deformed by the object, and at least one of the nanotips may mechanically interlock the edge of the object. In other words, the edge of the object is embedded while deforming an inclined surface of the nanotips, thereby exhibiting a locking force based on mechanical interlocking in addition to an attachment force based on the contact between the attachment surface and the top surface of the object. In this case, the edges in opposite directions among the edges of the object respectively interlock with different nanotips, thereby exhibiting strong adhesion.

Meanwhile, in some cases, the edge of the object may be not adhered but attached to the inclined surface of the nanotips. In this case, the attachment may be achieved only by contact between the top surface of the object and the plurality of nanotips.

The cooling step S400, in which the pressed nanotips are cooled below the critical temperature, refers to a step of cooling the stamp below the critical temperature, i.e., the glass transition temperature in order to fix the object attached to the stamp. According to the characteristics of the shape memory polymer, the nanotips may become a hard glassy state below the glass transition temperature.

The cooling in this step S400 may be achieved by at least one of conduction cooling, convection cooling, and radiational cooling.

The aligning step S500, in which the attached object is aligned on the receiving substrate, refers to a step of aligning the horizontal and vertical positions of the receiving substrate and the stamp. First, the horizontal position may be aligned while picking up the object above the receiving substrate. Then, the distance between the stamp and the receiving substrate is adjusted to become closer until the object is at a target position on the receiving substrate.

The transferring step S600, in which the nanotips arranged on the receiving substrate are heated to the critical temperature or higher so as to transfer a transfer object to the receiving substrate, refers to a step of heating the stamp with the nanotips again to the glass transition temperature or higher.

In this step, when the nanotips are heated to the glass transition temperature or higher, the nanotips may become an unpressed state due to restoration force. In other words, the nanotip may be changed in shape to have a smaller cross-sectional area toward the end thereof. As a result, the surface contact between the nanotip and the object is changed into a point contact, and the nanotips in the edge portions are released from the interlocking.

In the foregoing steps S100 to S600, the stamp is entirely configured to perform the transfer. However, the stamp based on the shape memory polymer nanotips according to the disclosure may be partially configured to perform the transfer. In this case, the heating step S100, the cooling step S400, and the transferring step S600 may be performed only for some nanotips. In other words, a portion of the stamp may be independently heated and cooled to selectively determine a transfer area.

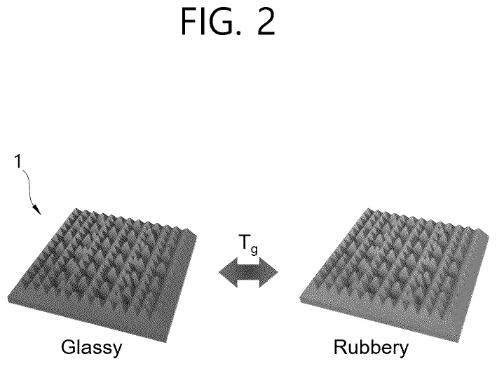

Below, the characteristics and use of the stamp based on the shape memory polymer nanotips according to the disclosure will be described in detail with reference to FIGS. 2 to 15.

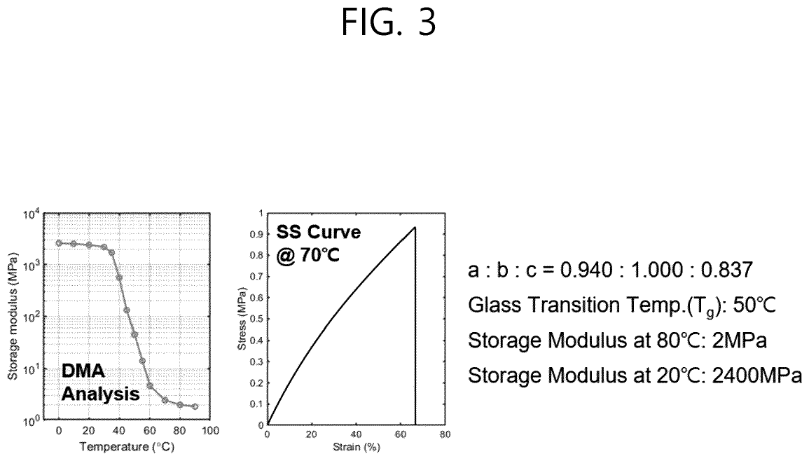

FIG. 2 is a conceptual diagram showing the characteristics of a stamp based on shape memory polymer nanotips according to the disclosure, which is varied depending on temperature, and FIG. 3 is a graph showing the characteristics of a stamp based on shape memory polymer nanotips according to the disclosure, which is varied depending on temperature.

Referring to FIGS. 2 and 3, the stamp based on the shape memory polymer nanotips according to the disclosure may reversibly alter between the soft rubbery state and the hard glassy state with respect to the glass transition temperature (Tg) as described above. For example, the glass transition temperature may be 50° C. According to an embodiment, the stamp has a storage modulus of 2 Mpa at 80° C. higher the glass transition temperature, and has a storage modulus of 2400 Mpa at 20° C. lower than the glass transition temperature.

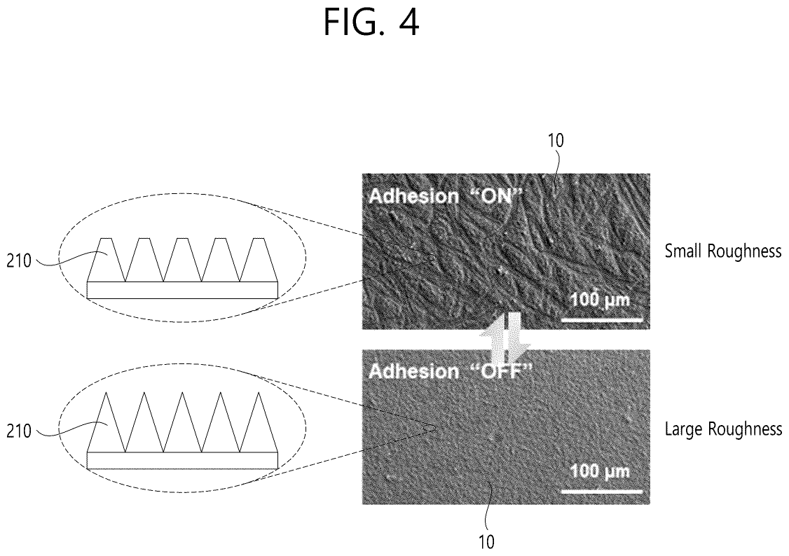

FIG. 4 shows surface images of a stamp based on shape memory polymer nanotips when turned on/off, along with conceptual diagrams of the nanotips.

According to the disclosure, an adhesive surface of the stamp may have ‘surface roughness’ defined by a plurality of nanotips 210. The roughness on the adhesive surface of the roughness may be varied depending on difference between an average height of the nanotips 210 and a height of an individual tip. According to the disclosure, an attachment surface 10 of the stamp may have small surface roughness as the nanotips are deformed when pressed against the object. Further, the attachment surface 10 of the stamp may have large surface roughness when the nanotips 210 are restored to their original shapes.

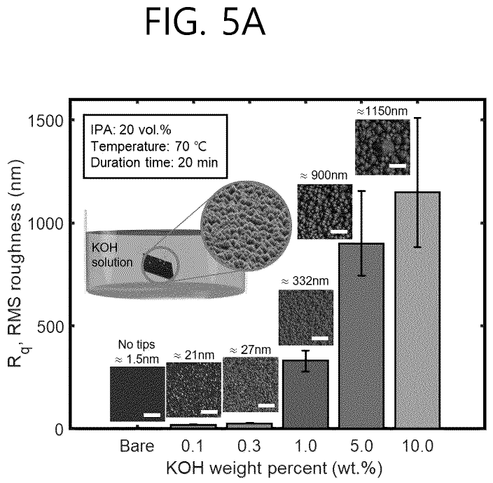

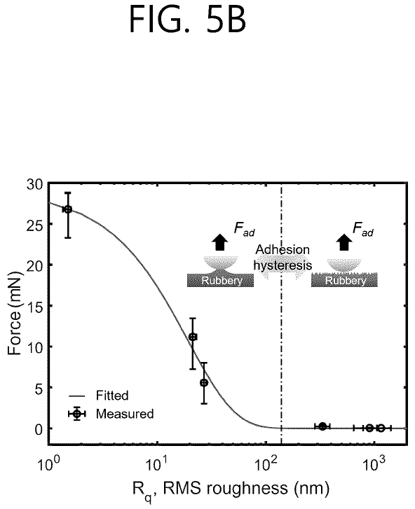

FIGS. 5A and 5B are graphs showing relationships between the roughness and adhesion on an attachment surface of a stamp according to the disclosure.

Referring to FIG. 5A, the roughness of the attachment surface increases as a function of the concentration of a KOH solution which forms the silicon mold of the attachment surface. Here, wt. % represents the concentration of KOH in the solution. It will be understood that the size of nanotips in the stamp increases as the concentration of KOH increases. As the size of nanotips increases, the roughness increases. For example, when KOH is 10 wt. %, in other words, when the concentration is the largest, the roughness is the largest.

Referring to FIG. 5B, the roughness and adhesion of the stamp are inversely proportional to each other. On the other hand, the contact area and adhesion of the stamp are proportional to each other from a microscopic perspective. In conclusion, the adhesion of the stamp decreases as the surface roughness increases. Based on such relationships, the adhesion is controlled by controlling the ‘roughness’ of the shape memory polymer nanotips.

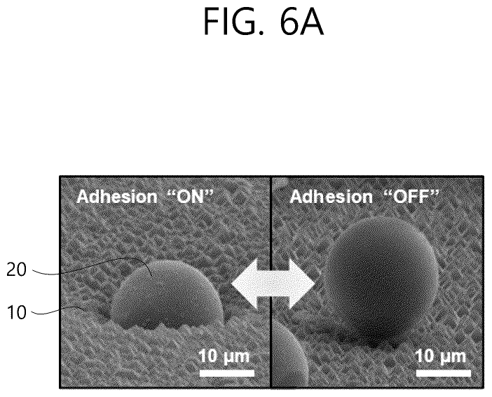

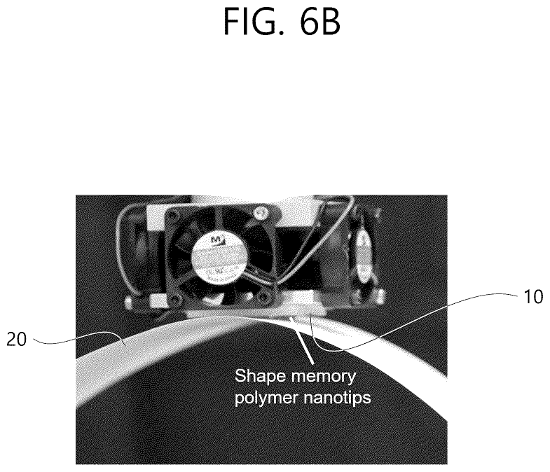

FIGS. 6A and 6B are images showing that an object is picked up by a stamp based on shape memory polymer nanotips according to the disclosure.

Referring to FIG. 6A, an object according to the disclosure may be smaller than the stamp. For example, the object to be transferred may be the object on a microscopic scale (1 mm or less). In this case, the surface roughness of the stamp decreases as the shape memory polymer nanotips are deformed, thereby increasing the adhesion for the object. On the other hand, the surface roughness of the stamp increases as the shape memory polymer nanotips are restored, thereby decreasing the adhesion for the object.

Referring to FIG. 6B, an object according to the disclosure may be larger than the stamp. For example, the object to be transferred may be on a macroscopic scale (1 mm or more). Even in this case, the adhesion is controlled by controlling the ‘surface roughness’ of the stamp as described above, thereby picking up and placing the object.

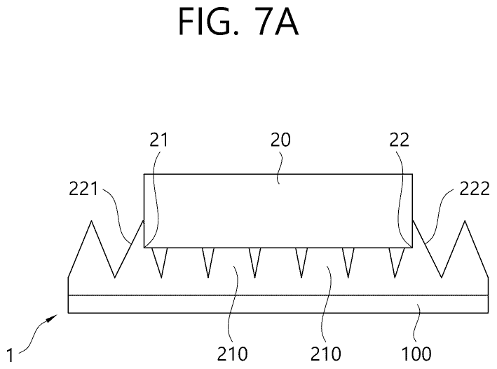

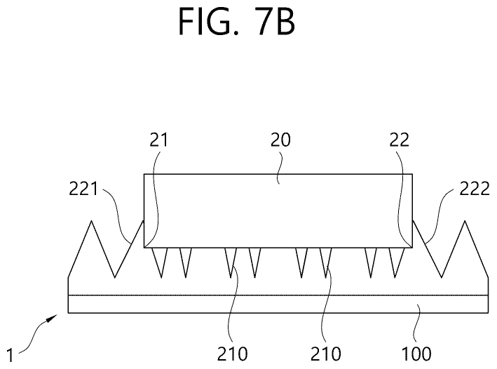

FIGS. 7A and 7B are conceptual diagrams showing another example that an object is picked up by a stamp based on shape memory polymer nanotips according to the disclosure.

The principle of the transfer may be similarly applied regardless of whether the nanotips are arranged on a support layer 100 of a stamp 1 regularly (see FIG. 7A) or irregularly (see FIG. 7B). According to the disclosure, the size of object 20, i.e. an object to be attached may be larger than the size of nanotips. Therefore, the stamp 1 according to the disclosure allows the plurality of nanotips to attach the object 20 together.

Referring to FIG. 7A, the plurality of nanotips is provided as arranged in the stamp 1. In this case, the plurality of nanotips may be divided into first nanotips 210 that come into contact with the surface of the object 20, and second nanotips 221 and 222 that come into contact with the edges 21 and 22 of the object 20 according to shapes in which they are pressed. Of course, there may be nanotips that are not used to come into contact with the object 20. In this case, the first nanotips 210 may be gradually deformed as the object 20 or the stamp 1 is pressed. Because the nanotips are shaped to have smaller cross-sectional areas toward the ends thereof, the area of the contact surface may increase as pressed against the object 20.

On the other hand, the second nanotips 221 and 222, of which the inclined surfaces are in contact with which the edges of the object 20, receive force through the inclined surfaces as the object 20 or the stamp 1 is pressed. As a result, the inclined surfaces are deformed corresponding to and interlocking with the edges of the object 20. In this case, referring to FIG. 7A, the left edge 21 and the right edge 22 simultaneously interlock with the left second nanotips 221 and the right second nanotips 221, respectively, thereby exhibiting strong a locking force.

Referring to FIG. 7B, the foregoing locking principle is equally applied event though the nanotips 210, 221, and 222 are irregularly formed on the attachment surface of the stamp. Although the first nanotips 210 are different in position and size from one another, the contact surface of the object 20 may cause at least one of the first nanotips 210 to have a flat contact surface. Further, even though the second nanotips 221 and 222 to come into contact with the edges of the object 20 are different in size from one another, the second nanotips 221 and 222 mechanically interlock with the object 20 as the edges 21 and 22 are embedded in the inclined surface.

Meanwhile, the plurality of nanotips are provided on the attachment surface 10 of the stamp according to the disclosure, and spaces are present between the ends of the nanotips 210, 221 and 222. Thus, the nanotips are not significantly resisted by the adjacent nanotips 210, 221 and 222 when deformed as pressed against the object 20. This principle may be equally applied regardless of whether nanotips are provided regularly (FIG. 7A) or irregularly (FIG. 7B).

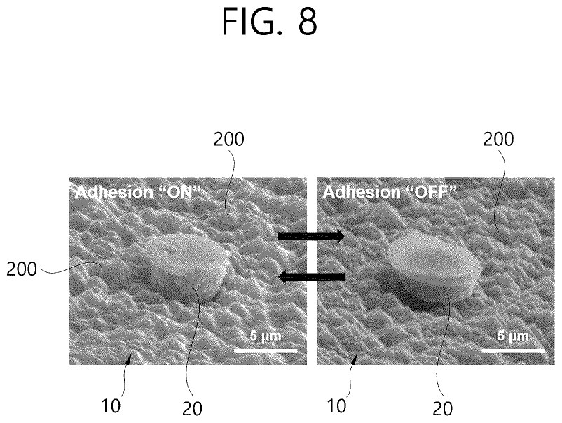

FIG. 8 shows images of an object picked up by a stamp based on shape memory polymer nanotips according to the disclosure.

Referring to FIG. 8, the object 20 is attached to and released from the stamp on which the nanotips 200 are irregularly provided as shown in FIG. 7B. The left image shows that the object 20 is attached while deforming the plurality of nanotips 200 through pressing and cooling. In this case, some nanotips 200 are interlocking with the edges of the object 20. In this state, the object 20 is separable from a donor substrate.

The right image in FIG. 8 shows that the plurality of nanotips 200 are restored to their original shapes and the adhesion is released when the stamp is heated to the glass transition temperature or higher and external force is removed. In this state, the adhesion may be extremely lowered as at least one nanotip 200 loses its contact surface and comes into point-contact with the object 20. In this state, the object 20 is transferable to the receiving substrate.

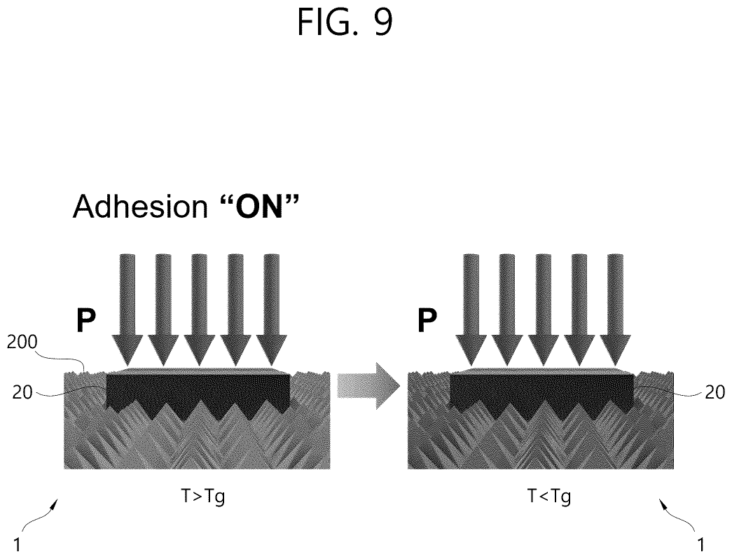

FIG. 9 is a conceptual diagram showing a process of picking up a stamp based on shape memory polymer nanotips according to the disclosure.

Referring to FIG. 9, the stamp 1 with the shape memory polymer nanotips 200 is heated to the glass transition temperature or higher and pressed against the object 20 through the heating step S100, the contacting step S200 and the pressing step S300 as described above.

Then, the cooling step S400 may be performed in the state that the object 20 and the stamp 1 are pressed against each other. In the cooling step S400, the stamp 1 is cooled to a temperature lower than the glass transition temperature, and the plurality of nanotips 200 are finally cooled. Because the shapes of the plurality of nanotips 200 are maintained while interlocking with the object 20, a strong locking force is maintained. Therefore, the object 20 is stably transferred using the stamp 1.

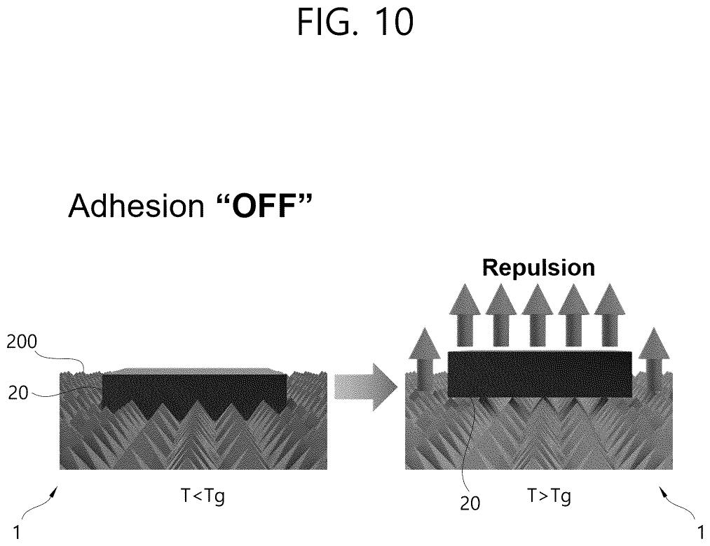

FIG. 10 is a conceptual diagram showing a process of releasing a stamp based on shape memory polymer nanotips according to the disclosure.

Referring to FIG. 10, in order to release the object 20 in the foregoing transferring step S600, the stamp 1, to which the object 20 is locked below the glass transition temperature, may be heated to the glass transition temperature or higher. In this case, when the stamp 1 is heated under the condition that external pressure is removed, the object 20 is pushed out by the restoration force of the plurality of nanotips 200. Eventually, the adhesion between the nanotips 200 and the object 20 is extremely lowered, and the stamp 1 is separated after attaching the other side (the top surface in FIGS. 7A and 7B) of the object 20 to the receiving substrate. In this case, the object 20 is released from the stamp 1 because the adhesion on the top surface of the object 20 is stronger than the adhesion on the bottom surface of the object 20.

For the convenience of description, FIGS. 9 and 10 show that the object 20 is picked up and released from above the stamp 1, but this is merely an example. The foregoing processes may be equally applied even when the object 20 is picked up and released from below the stamp 1.

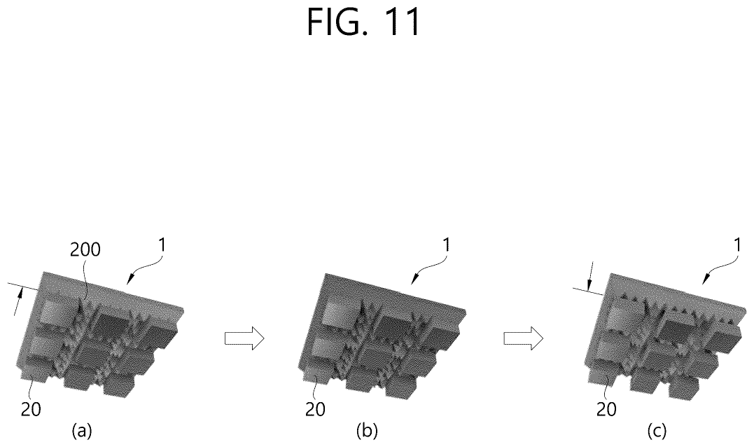

FIG. 11 is a conceptual diagram showing a mass-transfer process using a stamp based on shape memory polymer nanotips according to the disclosure.

Referring to FIG. 11, the stamp 1 based on the shape memory polymer nanotips 200 heated to the glass transition temperature or higher may be pressed against a plurality of arranged objects 20 (left). Then, the stamp 1 pressed against the objects 20 is cooled below the glass transition temperature (center). In this case, each object 20 is attached and locked to the plurality of nanotips 200 for each area of the stamp 1. Then, under the condition that the pressure is released, the stamp 1 is heated to the glass transition temperature or higher, so that a large number of objects 20 are released simultaneously (right).

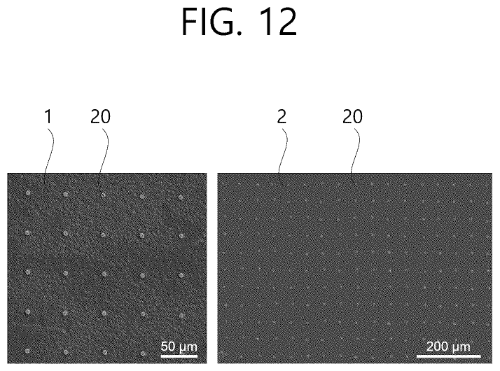

FIG. 12 shows result images of object mass-transferred using a stamp based on shape memory polymer nanotips according to the disclosure.

The left image in FIG. 12 shows a case where the plurality of objects arranged on the stamp based on the shape memory polymer nanotips are picked up. The right image in FIG. 12 shows a final result of the transfer, in which a large number of objects are transferred onto the PDMS receiving substrate by the transfer method using the stamp based on the shape memory polymer nanotips according to the disclosure.

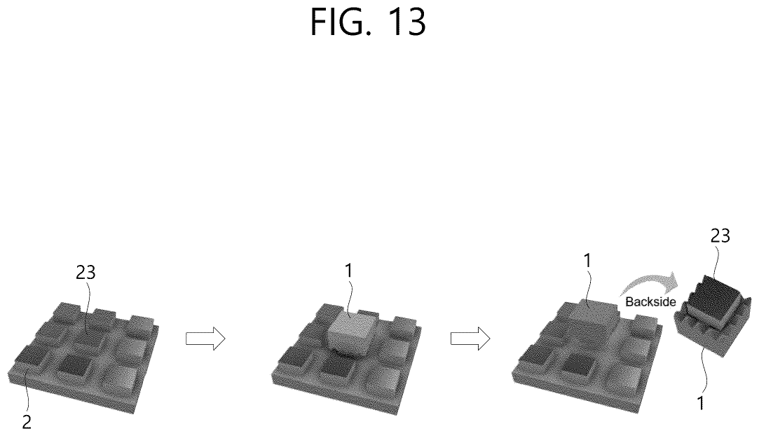

FIG. 13 is a conceptual diagram showing that a micro-LED is replaced using a stamp 1 based on shape memory polymer nanotips according to the disclosure.

Referring to FIG. 13, the transfer method using the stamp 1 based on the shape memory polymer nanotips according to the disclosure enables partial transfer, and is thus usable in not only producing products but also replacing micro-scale parts. For example, the stamp 1 according to the disclosure can pick up and release out only a micro-LED 23 required to be replaced from the array of the micro-LEDS 23 that have already been transferred to the substrate 2. Further, the stamp 1 can pick up and place a new micro-LED 23 for replacement from the outside. Such partial picking-up and placing operations may be performed by resizing the stamp 1 based on the shape memory polymer nanotips into a size capable of picking up a micro-scale object. When a relatively large stamp 1 is used, only a part of the stamp 1 may be heated and cooled to pick up one micro-LED 23 and thus used for the partial transfer.

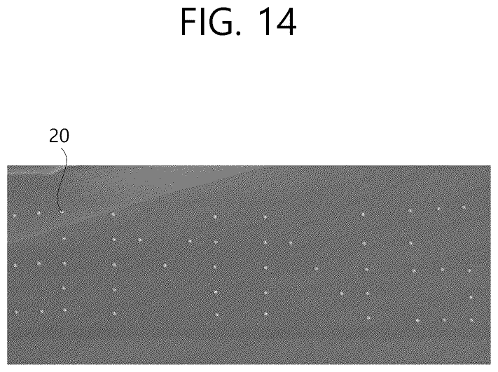

FIG. 14 shows a result image of object selectively transferred using a stamp based on shape memory polymer nanotips according to the disclosure.

FIG. 14 shows that “3MNS” is patterned by removing some silicon chips transferred to the PDMS receiving substrate from the shape memory polymer nanotips. The transfer method according to the disclosure may be applied to repairing technology for removing the already transferred object 20 from the receiving substrate.

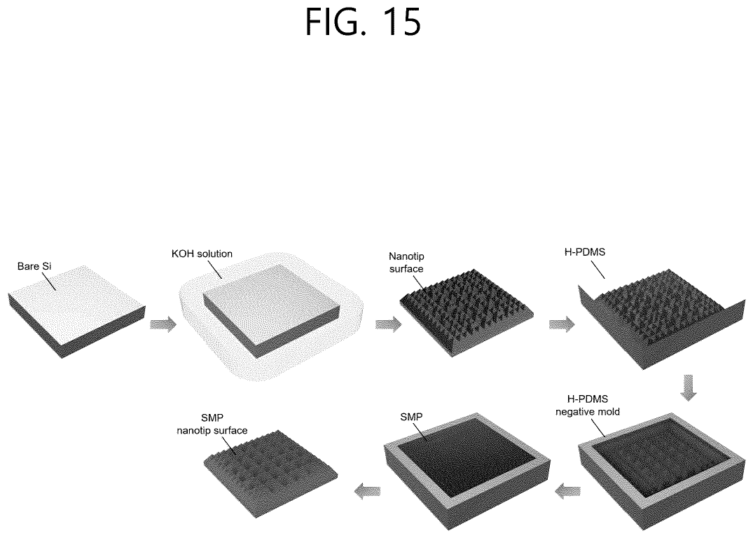

FIG. 15 is a conceptual diagram showing a method of fabricating a stamp based on shape memory polymer nanotips according to the disclosure.

First, bare silicon having a crystal orientation of 100 is put into a KOH solution to form nanotips. Then, H-PDMS is poured to the silicon formed with nanotips, and a soft lithography process is performed to form a negative mold. H-PDMS can imitate nanostructures more clearly than PDMS. In this case, a silane coating process may be additionally performed so that the silicon can be easily separated from the H-PDMS mold.

Then, a shape memory polymer precursor is poured into the negative H-PDMS mold obtained from the silicon. Then, the poured shape memory polymer precursor is cured as treated at a temperature of 120° C. for about 1 hour.

The cured shape memory polymer is separated from the H-PDMS mold, thereby completing the fabrication.

As described above, a method of transferring an object using a stamp with shape memory polymer nanotips according to the disclosure employs the shape memory polymer nanotips, the adhesion of which is highly reversible, and it is thus easy to control the adhesion. Further, the object transfer method based on the shape memory polymer nanotips according to the disclosure may be applied to various fabrication processes because the mass-transfer and the selective transfer of the object are possible.

By a method of transferring an object using a stamp with shape memory polymer nanotips according to the disclosure, the attachment surface has high adhesion reversibility, thereby achieving a high yield in a mass transfer process. Further, the strong adhesion makes it easy to remove an object that has already been transferred to the receiving substrate, and the method according to the disclosure is applicable to the micro-LED repairing technology.

Further, the shape memory polymer stamp proposed according to the disclosure is fabricated using inexpensive materials, has a simple fabrication process, and is highly reusable, thereby having effects on reducing the total costs of the transfer technology system.

In addition, a later assistant system may be used to transfer only a specific object, thereby having an effect on improving selectivity in mass transfer. Further, the shape memory polymer may be mixed with other materials to increase a heating reaction speed, thereby having an effect on reducing a process time.

These effects of the disclosure ensure that micro-scale structures can be quickly transferred to a final receiving substrate and accurately transferred without contamination or damage, and thus effectively applicable to the transfer of a semiconductor device such as a thin film transistor and an interposer; the mass fabrication based on heterogeneous integration technology; a large-area mass transfer technology for a micro-LED, a quantum dot display, etc. Accordingly, the disclosure is expected to make a considerable contribution to the development and commercialization of semiconductor and display technologies.

What is claimed is:

1. A method of transferring an object using a stamp with shape memory polymer nanotips, the method comprising:
a heating step in which a plurality of nanotips provided on an attachment surface is heated to a critical temperature or higher;
a contacting step in which at least one of the nanotips comes into contact with the object;
a pressing step in which the attachment surface is at least partially decreased in roughness to attach the object thereto;
a cooling step in which the nanotips in a pressed state are cooled below the critical temperature;
an aligning step in which the an object attached to the stamp is arranged on a receiving substrate; and
a transferring step in which the nanotips arranged on the receiving substrate are heated to the critical temperature or higher to transfer a micro-sized an object to the receiving substrate.

2. The method of claim 1, wherein, in the pressing step, the stamp is decreased in surface roughness by the object.

3. The method of claim 2, wherein
in the contacting step, an outer surface of at least one of the nanotips and an edge of the object come into contact with each other at an angle, and
in the pressing step, the object and the plurality of nanotips interlock with each other as at least two among the edges of the object deform the nanotips.

4. The method of claim 3, wherein the stamp comprises the nanotips regularly or randomly arranged on the attachment surface.

5. The method of claim 4, wherein the nanotip is smaller than the object.

6. The method of claim 5, wherein the nanotip is at least partially shaped to have a smaller cross-sectional area toward an end portion thereof.

7. The method of claim 6, wherein, in the contacting step,
an end portion of at least one first nanotip comes into contact with the object, and
an inclined surface of at least one second nanotip comes into contact with the object.

8. The method of claim 7, wherein, in the pressing step, a contact surface is formed as the first nanotips is pressed against the object.

9. The method of claim 8, wherein, in the pressing step, the edge of the object is at least partially embedded in the second nanotips.

10. The method of claim 9, wherein, in the pressing step, a plurality of edges of the object are simultaneously embedded in the plurality of second nanotips.

11. The method of claim 10, wherein, in the pressing step, the opposite edges of the object are simultaneously embedded in the second tips.

12. The method of claim 11, wherein, in the transferring step, the contact surface disappears as the first nanotips are restored to their original shapes.

13. The method of claim 12, wherein the embedment in the second nanotips is released as the second nanotips are restored to their original shapes.

14. The method of claim 2, wherein the heating step is performed by heating the nanotips to the glass transition temperature or higher.

15. The method of claim 14, wherein the heating step is performed by at least one of laser assisted heating, resistive heating, conduction heating, and convection heating.

16. The method of claim 15, wherein
the nanotips are provided on a support layer, and
the support layer is made of a material that is less thermally deformed than the nanotips.

17. The method of claim 2, wherein the cooling step is performed by cooling the nanotips below the glass transition temperature.

18. The method of claim 17, wherein the cooling step is performed by at least one of conduction cooling, convection cooling, and radiational cooling.

19. The method of claim 2, wherein the heating step, the cooling step, and the transferring step are performed for a portion of the stamp.

20. The method of claim 19, wherein at least some among a plurality of objects arranged on an area of the stamp are selectively transferred.
